(19) United States
(12) Patent Application Publication
(10) Pub. No.: US 2026/0156838 A1
(43) Pub. Date: Jun. 4, 2026

(54) SEMICONDUCTOR DEVICE AND ELECTRONIC SYSTEM INCLUDING THE SAME

(71) Applicant: SAMSUNG ELECTRONICS CO., LTD., Suwon-si (KR)

(72) Inventors: Kang Lib KIM, Suwon-si (KR); Yunjo Lee, Suwon-si (KR); Jaehoon Lee, Suwon-si (KR); Dongjin Lee, Suwon-si (KR); Jaeduk Lee, Suwon-si (KR)

(73) Assignee: SAMSUNG ELECTRONICS CO., LTD., Suwon-si (KR)

(21) Appl. No.: 19/354,373

(22) Filed: Oct. 9, 2025

(30) Foreign Application Priority Data
Dec. 2, 2024 (KR) 10-2024-0176704

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/792

(57) ABSTRACT

A semiconductor device may include: a first peripheral circuit structure including a first semiconductor substrate, and a first peripheral circuit on the first semiconductor substrate; a second peripheral circuit structure vertically overlapping with the first peripheral circuit structure, the second peripheral circuit structure including a second semiconductor substrate, and a second peripheral circuit on the second semiconductor substrate; and a cell array structure vertically overlapping with the first peripheral circuit structure and the second peripheral circuit structure, the cell array structure including memory cells that are three-dimensionally arranged, wherein the first peripheral circuit structure includes a first wiring structure including a first bonding pad, the first bonding pad connected to the first semiconductor substrate, and wherein the second peripheral circuit structure includes a second wiring structure including a second bonding pad, the second bonding pad connected to the second semiconductor substrate and bonded to the first bonding pad.

### CROSS-REFERENCE TO RELATED APPLICATIONS

This application claims priority under 35 U.S.C. § 119 to Korean Patent Application No. 10-2024-0176704, filed on Dec. 2, 2024, in the Korean Intellectual Property Office, the disclosure of which is incorporated by reference herein in its entirety.

### BACKGROUND

The present disclosure relates to a semiconductor device and an electronic system including the same.

There is a need for a semiconductor device that can store a large amount in an electronic system that requires data storage. Accordingly, a method for increasing data storage capacity of the semiconductor device is being researched. For example, a semiconductor device including memory cells three-dimensionally arranged is being proposed instead of memory cells two-dimensionally arranged as one of methods for increasing the data storage capacity of the semiconductor device.

### SUMMARY

Some embodiments of the disclosure provide a semiconductor device which may have improved reliability and integration.

Some embodiments of the disclosure provide an electronic system including a semiconductor device.

Problems solved by embodiments of disclosure are not limited to the problems mentioned above, and other problems solved by embodiments of disclosure not mentioned may be clearly understood by those skilled in the art from the description below.

According to an aspect of the disclosure, a semiconductor device may be provided and include: a first peripheral circuit structure including a first semiconductor substrate, and a first peripheral circuit on the first semiconductor substrate; a second peripheral circuit structure vertically overlapping with the first peripheral circuit structure, the second peripheral circuit structure including a second semiconductor substrate, and a second peripheral circuit on the second semiconductor substrate; and a cell array structure vertically overlapping with the first peripheral circuit structure and the second peripheral circuit structure, the cell array structure including memory cells that are three-dimensionally arranged, wherein the first peripheral circuit structure includes a first wiring structure including a first bonding pad, the first bonding pad connected to the first semiconductor substrate, and wherein the second peripheral circuit structure includes a second wiring structure including a second bonding pad, the second bonding pad connected to the second semiconductor substrate and bonded to the first bonding pad.

According to an aspect of the disclosure, a semiconductor device may be provided and include: a first peripheral circuit structure including: a first semiconductor substrate; a first peripheral circuit on the first semiconductor substrate; and a first bonding pad connected to the first semiconductor substrate. The semiconductor device may further include: a second peripheral circuit structure vertically overlapping with the first peripheral circuit structure; and a cell array structure vertically overlapping with the first peripheral circuit structure and the second peripheral circuit structure, the cell array structure including memory cells that are three-dimensionally arranged, wherein the second peripheral circuit structure includes: a second semiconductor substrate including a first surface and a second surface opposite to the first surface; a second peripheral circuit on the first surface of the second semiconductor substrate; a second bonding pad connected to the second surface of the second semiconductor substrate; a third bonding pad connected to the second peripheral circuit, the third bonding pad being on the first surface of the second semiconductor substrate; and a through plug penetrating the second semiconductor substrate and connecting the first peripheral circuit and the second peripheral circuit, and wherein the first bonding pad is bonded to the second bonding pad.

According to an aspect of the disclosure, an electronic system may be provided and include a semiconductor device including: a first peripheral circuit structure; a second peripheral circuit structure on the first peripheral circuit structure; and a cell array structure on the second peripheral circuit structure. The electronic system may further include a controller electrically connected to the semiconductor device via an input-output pad, the controller configured to control the semiconductor device, wherein the first peripheral circuit structure includes: a first semiconductor substrate; a first peripheral circuit on the first semiconductor substrate; a first connection wire connected to the first peripheral circuit, and a first bonding pad, wherein the second peripheral circuit structure includes: a second semiconductor substrate; a second peripheral circuit on a first surface of the second semiconductor substrate; a second connection wire connected to the second peripheral circuit; a second bonding pad connected to the second connection wire; and a third bonding pad bonded to the first bonding pad, and wherein the first bonding pad of the first peripheral circuit structure is connected to the first semiconductor substrate.

Specific details of other embodiments are included in the detailed description and the drawings.

### BRIEF DESCRIPTION OF DRAWINGS

The accompanying drawings are included to provide a further understanding of aspects of the disclosure, and are incorporated in and constitute a part of this specification. The drawings illustrate example embodiments of the disclosure and, together with the description, serve to explain example aspects of the disclosure. In the drawings:

FIG. 1 is a diagram illustrating a substrate on which semiconductor devices according to some embodiments of the disclosure are integrated;

FIG. 2 is a block diagram of a semiconductor device according to some embodiments of the disclosure;

FIG. 3 is a schematic perspective view of a semiconductor device according to some embodiments of the disclosure;

FIG. 4 is a cross-sectional view partially illustrating a semiconductor device according to some embodiments of the disclosure;

FIGS. 5A, 5B and 5C are enlarged views of portions P1, P2, and P3 of FIG. 4, respectively;

FIG. 6A is a schematic perspective view illustrating a semiconductor device according to some embodiments of the disclosure;

FIG. 6B is a schematic plan view of a peripheral circuit structure of a semiconductor device according to some embodiments of the disclosure;

FIGS. 7A and 7B are cross-sectional views partially illustrating a semiconductor device according to some embodiments of the disclosure, and illustrate cross-sections taken along a line I-I′ of FIG. 6B;

FIGS. 8, 9, 10 and 11 are cross-sectional views partially illustrating a semiconductor device according to some embodiments of the disclosure;

FIGS. 12 to 19 are cross-sectional view for describing a method for manufacturing a semiconductor device according to some embodiments of the disclosure;

FIG. 20 is a diagram schematically illustrating an electronic system including a semiconductor device according to some embodiments of the disclosure;

FIG. 21 is a perspective view schematically illustrating an electronic system including a semiconductor device according to some embodiments of the disclosure; and

FIGS. 22 and 23 are cross-sectional views schematically illustrating semiconductor packages according to some embodiments of the disclosure.

### DETAILED DESCRIPTION

Hereinafter, a semiconductor device according to non-limiting example embodiments of the disclosure and an electronic system including the same will be described with reference to the drawings in detail.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

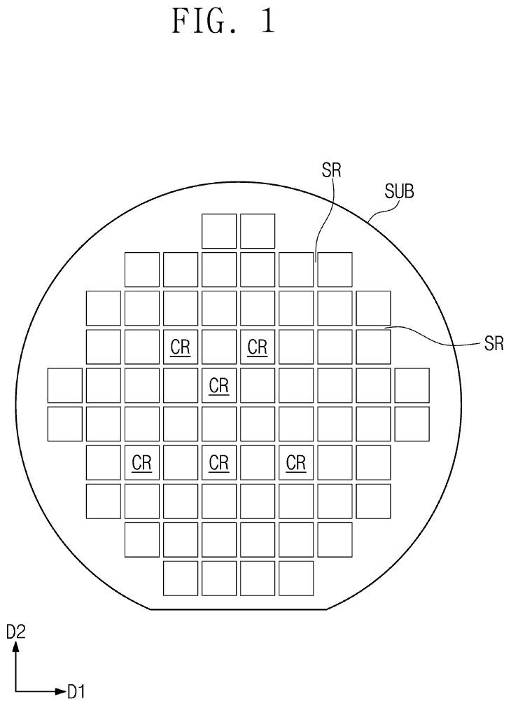

FIG. 1 is a diagram illustrating a substrate on which the semiconductor devices according to embodiments of the disclosure are integrated.

Referring to FIG. 1, a substrate SUB (e.g., a wafer) may include chip regions CR on which semiconductor chips are respectively formed, and a scribe lane region SR between the chip regions CR. The chip regions CR may be two-dimensionally arranged along a first direction D1 and a second direction D2 crossing each other. Each of the chip regions CR may be surrounded by the scribe lane region SR. That is, the scribe lane region SR may be disposed between the chip regions CR adjacent to each other in the first direction D1, and between the chip regions CR adjacent to each other in the second direction D2.

The semiconductor substrate SUB may be a bulk silicon substrate, a silicon-on-insulator (SOI) substrate, a germanium substrate, a germanium-on-insulator (GOI) substrate, a silicon-germanium substrate, or a substrate having an epitaxial thin-film obtained by performing a selective epitaxial growth (SEG).

According to embodiments, the semiconductor device including memory cells three-dimensionally arranged may be formed on each of the chip regions CR of the semiconductor substrate SUB. According to embodiments, the semiconductor device may include a vertical NAND (VNAND) flash memory, a NOR flash memory, a resistive random access memory (RRAM), a phase-change random access memory (PRAM), a magnetoresistive random access memory (MRAM), a ferroelectric random access memory (FRAM), a spin transfer torque random access memory (STT-RAM), a dynamic random access memory (DRAM), or a combination thereof.

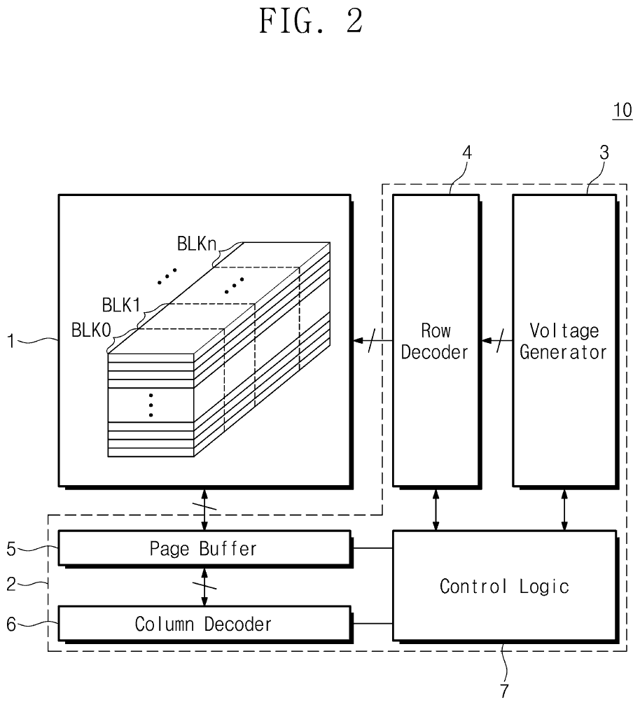

FIG. 2 is a block diagram of the semiconductor device according to an embodiment of the disclosure.

Referring to FIG. 2, a semiconductor device 10 may include a memory cell array 1 and a peripheral circuit 2 that controls the memory cell array 1. The peripheral circuit 2 may include a voltage generator 3, a row decoder 4, a page buffer 5, a column decoder 6, and control circuits 7 (e.g., control logic).

The memory cell array 1 may include a plurality of memory blocks BLK0 to BLKn. Each of the memory blocks BLK0 to BLKn may include memory cells three-dimensionally arranged. For example, each of the memory blocks BLK0 to BLKn may include structures stacked along a third direction D3 on a plane expanded along the first direction D1 and the second direction D2 crossing each other. The memory blocks BLK0 to BLKn may read data from or may write the data to a selected memory block in response to a corresponding block selection signal.

For example, the semiconductor device may be a vertical NAND flash memory device. In a case of the vertical NAND flash memory device, the memory blocks BLK0 to BLKn may include a plurality of NAND-type cell strings.

In another example, the semiconductor device may be a variable resistance memory device. In a case of the variable resistance memory device, the memory blocks BLK0 to BLKn may include memory cells respectively disposed on intersection points of word lines and bit lines. Here, each of the memory cells may include a resistive memory element. The resistive memory element may include perovskite compounds, transition metal oxide, a phase-change material, magnetic materials, ferromagnetic materials, or anti-ferromagnetic materials.

The voltage generator 3 may generate voltages (e.g., a program voltage, a read voltage, an erase voltage, or the like) for an internal operation of the memory cell array 1 in response to a control of the control circuit 7. Specifically, the voltage generator 3 may generate a word line voltage such as, for example, the program voltage, the read voltage, a pass voltage, an erase verification voltage, a program verification voltage, or the like. In addition, the voltage generator 3 may further generate a string selection line voltage and a ground selection line voltage on the basis of a voltage control signal.

The row decoder 4 may select one among the memory blocks BLK0 to BLKn by decoding an address input from an outside thereof, and may select any one among word lines of the selected memory blocks BLK0 to BLKn.

For example, when the semiconductor device is the vertical NAND flash memory device, the row decoder 4 may include a word line driver and a ground selection line/string selection line driver. For example, the row decoder 4 may further include a pass transistor circuit, a block decoder, and a driving signal line decoder. The row decoder 4 may select one among a plurality of string selection lines, and one among a plurality of ground selection lines. For example, the row decoder 4 may apply a program voltage and a program verification voltage to the selected word line during a program operation, and may apply the read voltage to the selected word line during a reading operation.

The page buffer 5 may be connected to the memory cell array 1 through the bit lines to read information stored in the memory cells. The page buffer 5 may operate as a write driver or a sense amplifier. For example, the page buffer 5 may apply a voltage corresponding to data to be programmed to a bit line to store the data in the memory cell during the program operation. For example, the page buffer 5 may sense a current or voltage through the bit line to sense the programmed data during a program verification operation or the read operation.

The column decoder 6 may select any one among the bit lines by decoding an address input from an outside thereof. The column decoder 6 may provide data transfer path between the page buffer 5 and an external device (e.g., a memory controller).

On the basis of a command signal, an address signal and a control signal, the control circuits 7 may program data to the memory cell array 1, may read the data from the memory cell array 1, or may generate several control signals for erasing the data stored in the memory cell array 1.

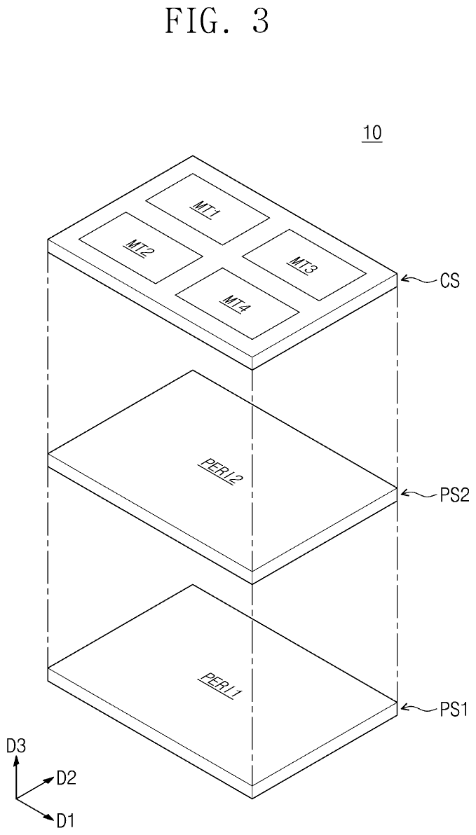

FIG. 3 is a schematic perspective view of the semiconductor device according to embodiments of the disclosure.

Referring to FIG. 3, the semiconductor device 10 according to embodiments of the disclosure may include a first peripheral circuit structure PS1, a second peripheral circuit structure PS2, and a cell array structure CS.

The cell array structure CS may include a plurality of mats MT1 to MT4 including a memory cell array. The plurality of mats MT1 to MT4 may be two-dimensionally arranged along the first direction D1 and the second direction D2. As described with reference to FIG. 2, each of the mats MT1 to MT4 may include the memory cell array 1 including the word lines, the bit lines and memory cells three-dimensionally arranged. That is, each of the mats MT1 to MT4 may include the plurality of memory cell blocks BLK1 to BLKn.

The cell array structure CS may vertically (e.g., in the third direction D3) overlap with the first peripheral circuit structure PS1 and the second peripheral circuit PS2. According to embodiments, the first peripheral circuit structure PS1 and the second peripheral circuit PS2 may include the peripheral circuit 2 (see FIG. 2) including the row and column decoders, the voltage generator, the page buffer, and the control circuits described with reference to FIG. 2.

The first peripheral circuit structure PS1 and the second peripheral circuit PS2 may be composed by dividing and disposing the peripheral circuit 2 (see FIG. 2) of the semiconductor device in a plurality of semiconductor substrates. For example, the first peripheral circuit structure PS1 may include peripheral circuits that operate at a low voltage. The second peripheral circuit structure PS2 may include peripheral circuits that operate at a high voltage.

A size of the semiconductor device may be reduced and integration of the semiconductor device may be improved by diving and disposing the peripheral circuits of the semiconductor device 10 in the first peripheral circuit structure PS1 and the second peripheral circuit PS2, and vertically stacking the first peripheral circuit structure PS1 and the second peripheral circuit PS2.

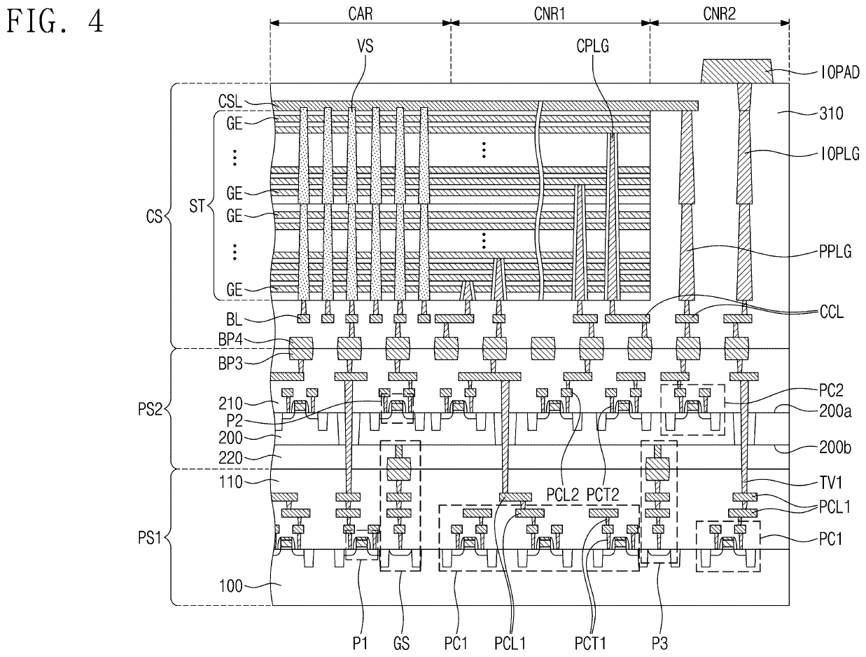

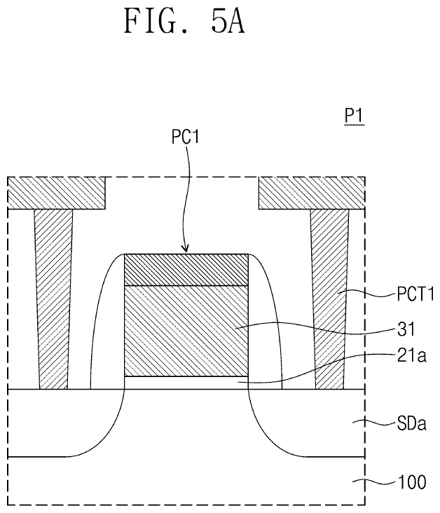

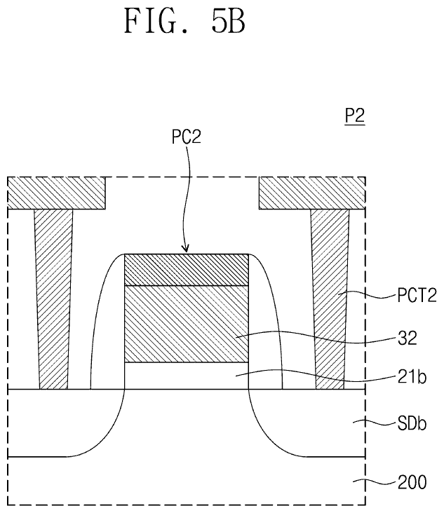

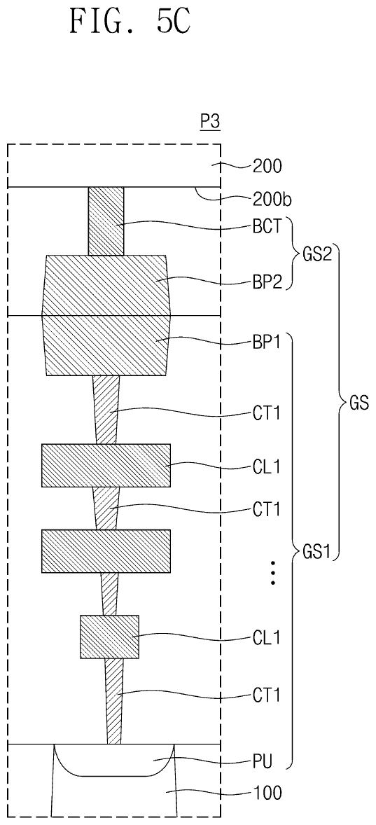

FIG. 4 is a cross-sectional view partially illustrating the semiconductor device according to some embodiments of the disclosure. FIGS. 5A, 5B and 5C are enlarged views of portions P1, P2, and P3 of FIG. 4, respectively.

Referring to FIG. 4, the semiconductor device according to some embodiments may include the first peripheral circuit structure PS1, the second peripheral circuit structure PS2 on the first peripheral circuit structure PS1, and the cell array structure CS on the second peripheral circuit structure PS2.

The first peripheral circuit structure PS1 may include first peripheral circuits PC1 integrated on a front surface of a first semiconductor substrate 100. The second peripheral circuit structure PS2 may include second peripheral circuits PC2 integrated on a front surface of a second semiconductor substrate 200.

According to some embodiments, a ground structure GS may be connected between the first semiconductor substrate 100 and the second semiconductor substrate 200. The ground structure GS may include a first wiring structure GS1 provided in the first peripheral circuit structure PS1, and a second wiring structure GS2 provided in the second peripheral circuit structure PS2. The ground structure GS may prevent an electric arc phenomenon from occurring in the second semiconductor substrate 200 due to an applied ground voltage during a process of manufacturing the semiconductor device.

Specifically, in a comparative embodiment, when the second semiconductor substrate 200 is electrically floated during bonding the first semiconductor substrate 100 and the second semiconductor substrate 200 and etching the second semiconductor substrate 200, positive charges may be accumulated on the second semiconductor substrate so that electric arcing may occur. However, according to embodiments, since the ground structure GS is provided between the first semiconductor substrate 100 and the second semiconductor substrate 200, the second semiconductor substrate 200 may be maintained in a grounded state during the process of manufacturing the semiconductor device to prevent the arcing phenomenon.

More specifically, the first peripheral circuit structure PS1 may include the first peripheral circuits PC1 that are integrated on the front surface of the first semiconductor substrate 100 and that control the memory cell array, and first connection wires PCL1 and first contact plugs PCT1 connected to the first peripheral circuits PC1.

For example, the first semiconductor substrate 100 may be a silicon substrate, a silicon-germanium substrate, a germanium substrate, or a single-crystalline epitaxial layer grown on a single-crystalline silicon substrate.

The first peripheral circuits PC1 may include the voltage generator 3, the row decoder 4, the page buffer 5, the column decoder 6 and the control circuit 7 described with reference to FIG. 2.

As illustrated in FIG. 5A, the first peripheral circuits PC1 may include low-voltage transistors integrated on the first semiconductor substrate 100. The first peripheral circuits PC1 may include a first gate insulating pattern 21a, a first gate electrode 31, and first source and drain regions SDa. The first gate electrode 31 may be disposed on an upper surface of the first semiconductor substrate 100. The first gate insulating pattern 21a may be disposed between the first semiconductor substrate 100 and the first gate electrode 31. The first gate insulating pattern 21a may be thinner than a second gate insulating pattern 21b (see FIG. 5B).

According to embodiments, the first peripheral circuit structure PS1 may include the first wiring structure GS1 including a first bonding pad BP1 connected to the first semiconductor substrate 100.

Referring to FIG. 5C, the first bonding pads BP1 may be disposed in an uppermost layer of a first peripheral circuit insulating layer 110 of the first peripheral circuit structure PS1. The first bonding pads BP1 may be connected to the first semiconductor substrate 100 through first contacts CT1 and first conductive patterns CL1. For example, the first bonding pads BP1 may be formed of copper. The first semiconductor substrate 100 may include a pick-up impurity region PU that may be a P-type or N-type impurity region, and the first bonding pads BP1 may be connected to the pick-up impurity region PU.

The second peripheral circuit structure PS2 may include the second semiconductor substrate 200, the second peripheral circuits PC2, second bonding pads BP2, and third bonding pads BP3.

For example, the second semiconductor substrate 200 may be a silicon substrate, a silicon-germanium substrate, a germanium substrate, or a single-crystalline epitaxial layer grown on a single-crystalline silicon substrate.

More specifically, the second semiconductor substrate 200 may have a first surface 200a and a second surface 200b opposite to the first surface 200a. The second peripheral circuits PC2 may be integrated on the first surface 200a of the second semiconductor substrate 200.

MOS transistors using the second semiconductor substrate 200 as a channel may be included. For example, the second peripheral circuits PC2 may include some of the voltage generator 3, the row decoder 4, the page buffer 5, the column decoder 6 and the control circuits 7 described with reference to FIG. 2. For example, the second peripheral circuits PC2 may include high-voltage transistors.

As illustrated in FIG. 5B, the second peripheral circuits PC2 may include the high-voltage transistors integrated on the second semiconductor substrate 200. The second peripheral circuits PC2 may include the second gate insulating pattern 21b, a second gate electrode 32, and second source and drain regions SDb.

The second gate electrode 32 may be disposed on the second semiconductor substrate 200. The second gate insulating pattern 21b may be disposed between the second semiconductor substrate 200 and the second gate electrode 32, and the second source and drain regions SDb may be provided on opposite sides of the second gate electrode 32 in the second semiconductor substrate 200. In addition, second contact plugs PCT2 may be connected to the second source and drain regions SDb.

The second contact plugs PCT2 and second connection wires PCL2 may be connected to the second peripheral circuits PC2 on the first surface 200a of the second semiconductor substrate 200.

A second peripheral circuit insulating layer 210 may cover the second peripheral circuits PC2 on the first semiconductor substrate 100. The second peripheral circuit insulating layer 210 may include one insulating layer or a plurality of stacked insulating layers.

The third bonding pads BP3 of the second peripheral circuit structure PS2 may be disposed in an uppermost layer of the second peripheral circuit insulating layer 210 of the second peripheral circuit structure PS2. The third bonding pads BP3 may be connected to the second peripheral circuits PC2 through the second contact plugs PCT2 and the second connection wires PCL2. For example, the third bonding pads BP3 may be formed of copper.

Moreover, the second peripheral circuit structure PS2 may include first penetration plugs TV1 penetrating the second semiconductor substrate 200. The first penetration plugs TV1 may connect the second connection wires PCL2 of the second peripheral circuit structure PS2 and the first connection wires PCL1 of the first peripheral circuit structure PS1.

The third bonding pads BP3 may be electrically connected to the first peripheral circuits PC1 on the first semiconductor substrate 100 through the first penetration plugs TV1 penetrating the second semiconductor substrate 200.

According to embodiments, the second wiring structure GS2 may be provided on the second surface 200b of the second semiconductor substrate 200. The second wiring structure GS2 may be connected to the first wiring structure GS1 of the first peripheral circuit structure PS1 to constitute the ground structure GS.

Specifically, a backside insulating layer 220 may be disposed on the second surface 200b of the second semiconductor substrate 200, and the second wiring structure GS2 may be provided in the backside insulating layer 220. The second wiring structure GS2 may include the second bonding pads BP2 and a backside contact BCT.

The backside contact BCT may be in direct contact with the second surface 200b of the second semiconductor substrate 200. The second bonding pad BP2 may be disposed in the backside insulating layer 220. The second bonding pad BP2 may be connected to the second semiconductor substrate 200 through the backside contact BCT. For example, the second bonding pads BP2 may be formed of copper.

The backside insulating layer 220 may be in direct contact with the uppermost layer of the first peripheral circuit insulating layer 110 of the first peripheral circuit structure PS1. The second bonding pad BP2 may be in direct contact with the first bonding pad BP1 of the first peripheral circuit structure PS1.

The cell array structure CS may include a cell array region CAR, a first connection region CNR1, and a second connection region CNR2. The memory blocks BLK described with reference to FIG. 2 may be provided in the cell array region CAR, and connection structures (e.g., a cell contact plug CPLG, a peripheral contact plug PPLG, cell conductive lines CCL and input-output contact plugs IOPLG, and the like) connecting the memory cells and the first peripheral circuit structure PS1 and the second peripheral circuit PS2 may be provided in the first connection region CNR1 and the second connection region CNR2.

Specifically, the cell array structure CS may include a common source line CSL, a stack ST, vertical structures VS, bit lines BL, cell contact plugs CPLG, peripheral contact plugs PPLG, and input-output contact plugs IOPLG. In addition, the cell array structure CS may further include fourth bonding pads BP4 bonded to the third bonding pads BP3.

The stack ST may include conductive patterns GE and interlayered insulating layers alternately stacked along a direction (e.g., a vertical directional) perpendicular to the upper surface of the first semiconductor substrate 100.

For example, the conductive patterns GE may include at least one selected from among a doped semiconductor (e.g., doped silicon, or the like), metal (e.g., tungsten, molybdenum, nickel, copper, aluminum, or the like), conductive metal nitride (e.g., titanium nitride, tantalum nitride, or the like), or transition metal (e.g., titanium, tantalum, or the like). The interlayered insulating layers may include silicon nitride, silicon oxide, silicon oxynitride and/or a low-dielectric material. For example, the interlayered insulating layers may include high density plasma (HDP) oxide or tetraethyl orthosilicate (TEOS).

The stack ST may be disposed between separation structures extending parallel to each other along one direction. For example, the separation structures may include an insulating material such as silicon oxide. The stack ST of the cell array structure CS may be provided in plural. A plurality of stacks ST may extend parallel to each other along one direction.

For example, the stack ST may have a uniform thickness in the cell array region CAR and the first connection region CNR1. Alternatively, according to some embodiments, the conductive patterns GE of the stack ST may be stacked so as to have a step structure in a connection region (e.g., the first connection region CNR1 or the second connection region CNR2). That is, lengths of the conductive patterns GE may decrease in one direction extending away from the second peripheral circuit structure PS2.

According to embodiments, the ground structure GS in the first peripheral circuit structure PS1 and the second peripheral circuit PS2 may vertically overlap with the stack ST of the cell array structure CS.

Each of the conductive patterns GE may include a pad portion connected to the cell contact plug CPLG in the first connection region CNR1. The cell contact plugs CPLG may penetrate the stack ST to be respectively connected to the pad portions of the conductive patterns GE in the first connection region CNR1. The cell contact plugs CPLG may have different vertical lengths. The vertical lengths of the cell contact plugs CPLG may decrease in a direction towards the cell array region CAR. The cell contact plugs CPLG may have bottom surfaces (e.g., upper surface in FIG. 4) located at different levels from each other, and may have upper surfaces (e.g., bottom surfaces in FIG. 4) located at the same level as each other. Alternatively, the cell contact plugs CPLG may have the same vertical length, and may be connected to corresponding conductive patterns through sidewalls of each cell contact plug CPLG.

Insulating spacers may be disposed between the cell contact plugs CPLG and the stack ST. The insulating spacers may respectively surround the cell contact plugs CPLG. For example, the insulating spacers may include at least one from among silicon oxide, silicon nitride, silicon oxynitride, and a low-dielectric material.

The common source line CSL may be disposed on the stack ST. The common source line CSL may extend from the cell array region CAR to the first connection region CNR1. For example, the common source line CSL may include at least one selected from among a doped semiconductor (e.g., doped silicon, or the like), metal (e.g., tungsten, molybdenum, nickel, copper, aluminum, or the like), conductive metal nitride (e.g., titanium nitride, tantalum nitride, or the like), or transition metal (e.g., titanium, tantalum, or the like).

The peripheral contact plugs PPLG and the input-output contact plug IOPLG may be horizontally spaced apart from the stack ST in the second connection region CNR2 to be disposed in a cell interlayered insulating layer 310. The peripheral contact plugs PPLG may electrically connect the common source line CSL and the fourth bonding pads BP4 through conductive lines.

Each of the cell contact plugs CPLG, peripheral contact plugs PPLG, and input-output contact plugs IOPLG may include a barrier metal layer including conductive metal nitride (e.g., titanium nitride, tantalum nitride, or the like), and a metal layer including metal (e.g., tungsten, titanium, tantalum, or the like).

The bit lines BL may be connected to the vertical structures VS through contact plugs in the cell array region CAR.

The cell conductive lines CCL may electrically connect the cell contact plugs CPLG, the peripheral contact plugs PPLG, and the input-output contact plug IOPLG to the fourth bonding pads BP4 through the contact plugs.

For example, the bit lines BL and the cell conductive lines CCL may include at least one selected from among metal (e.g., tungsten, copper, aluminum, or the like), conductive metal nitride (e.g., titanium nitride, tantalum nitride, or the like), or transition metal (e.g., titanium, tantalum, or the like).

The fourth bonding pads BP4 may be provided in a lowermost layer of the cell interlayered insulating layer 310 of the cell array structure CS. The fourth bonding pads BP4 may be electrically connected to the bit lines BL, the conductive patterns GE, and the common source lines CSL. A surface of the cell interlayered insulating layer 310 may be in direct contact with a surface of the uppermost layer of the second peripheral circuit insulating layer 210 of the second peripheral circuit structure PS2.

The fourth bonding pads BP4 may be electrically and physically connected to the third bonding pads BP3 in a bonding manner. That is, the fourth bonding pads BP4 may be in direct contact with the third bonding pads BP3. The fourth bonding pads BP4 may substantially have the same form, width, or area as the third bonding pads BP3. The fourth bonding pads BP4 may include the same metal material as a metal material of the third bonding pads BP3. For example, the fourth bonding pads BP4 may be formed of copper.

The input-output contact plugs IOPLG may be disposed in an uppermost layer of the cell interlayered insulating layer 310 of the cell array structure CS. The input-output contact plugs IOPLG may be connected to input-output pads IOPAD. The input-output pads IOPAD may be electrically connected to the cell array structure CS, the first peripheral circuit structure PS1, and the second peripheral circuit PS2.

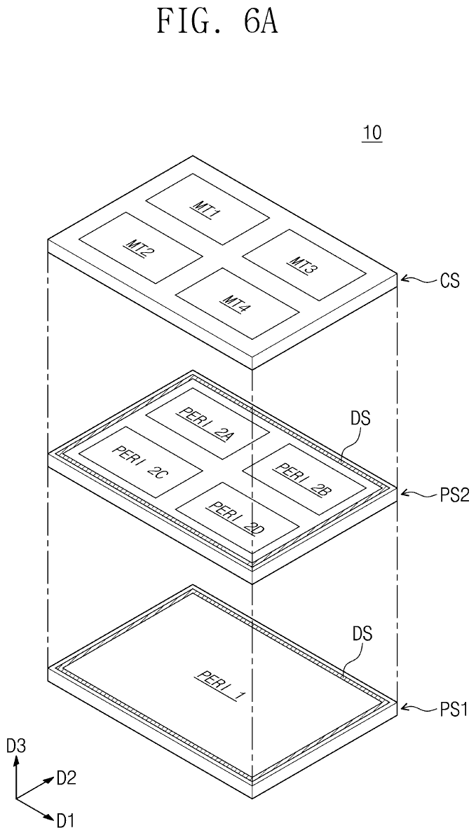

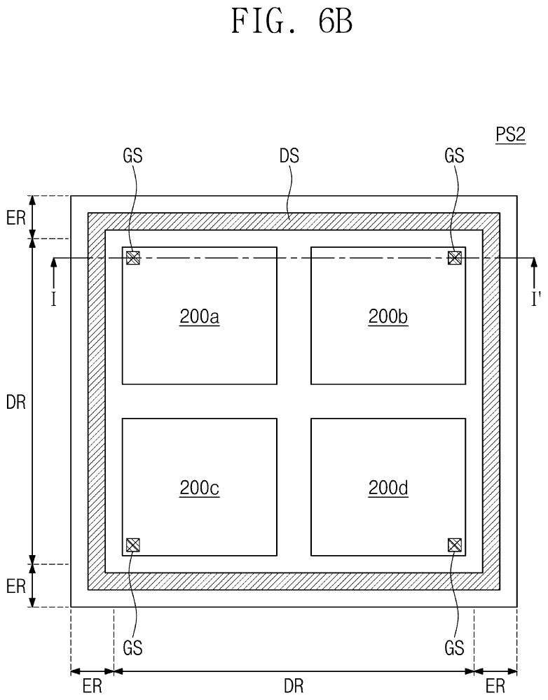

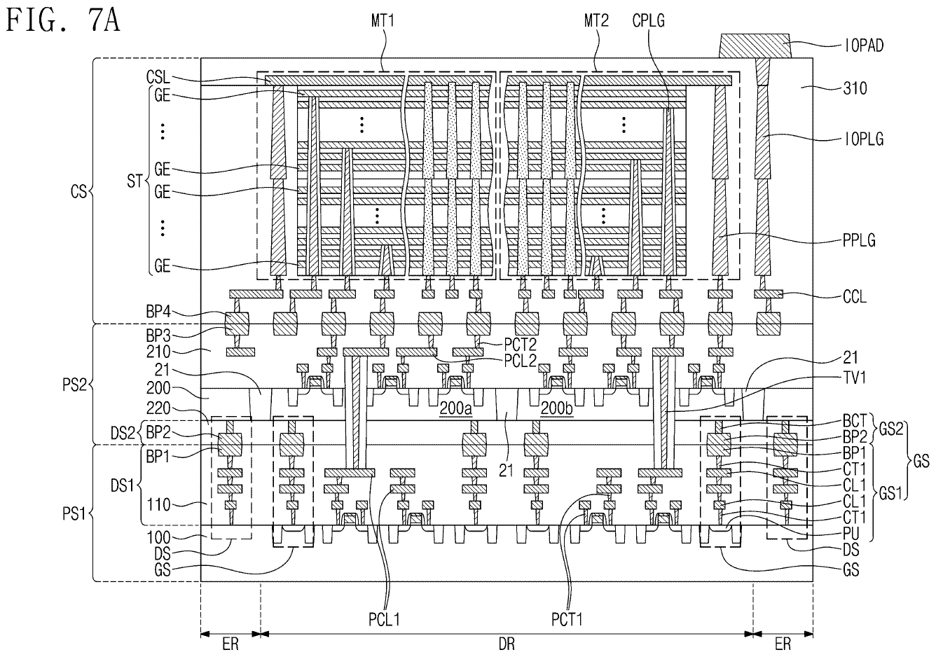

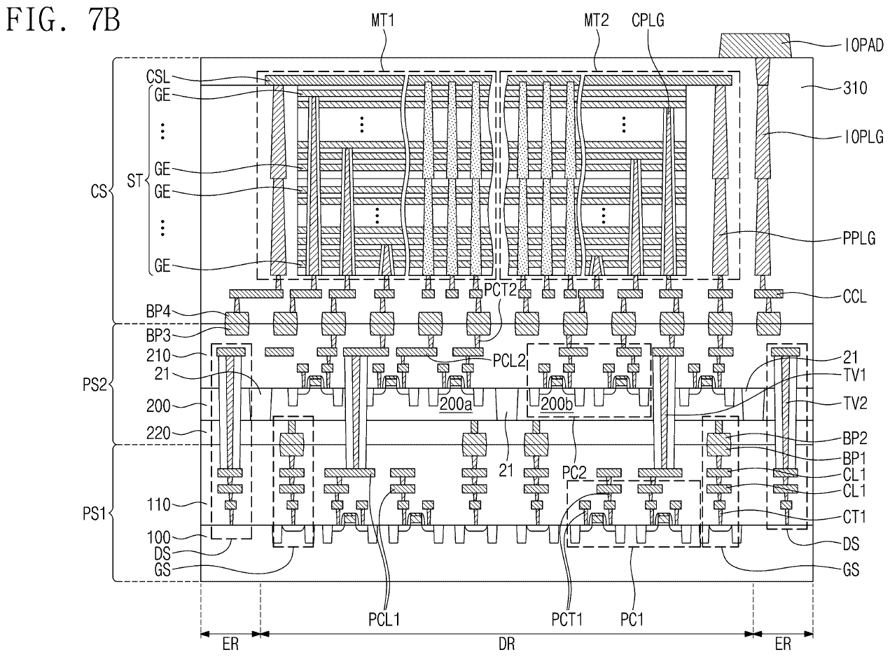

FIG. 6A is a schematic perspective view illustrating the semiconductor device according to embodiments of the disclosure. FIG. 6B is a schematic plan view of a peripheral circuit structure of the semiconductor device according to embodiments of the disclosure. FIGS. 7A and 7B are cross-sectional views partially illustrating the semiconductor device according to embodiments of the disclosure, and illustrate cross-sections taken along a line I-I′ of FIG. 6B. In order to simplify description, duplicate description for the same technical features as those of the semiconductor device described above may be omitted, and differences between embodiments will be described.

Referring to FIGS. 6A and 6B, the semiconductor device 10 according to embodiments may include the first peripheral circuit structure PS1, the second peripheral circuit PS2, and the cell array structure CS.

The cell array structure CS may include the plurality of mats MT1 to MT4 including the memory cell array.

According to embodiments, each of the first peripheral circuit structure PS1 and the second peripheral circuit PS2 may include the device region DR and an edge region ER surrounding the same. In each of the first peripheral circuit structure PS1 and the second peripheral circuit PS2, the peripheral circuits 2 described with reference to FIG. 2 may be provided in the device region DR, and a dam structure DS surrounding the peripheral circuits may be provided in the edge region ER.

According to embodiments, the second peripheral circuit structure PS2 may include a first sub-substrate 200a, a second sub-substrate 200b, a third sub-substrate 200c, a fourth sub-substrate 200d, and first to fourth sub-peripheral circuits PERI2A to PERI2D in the device region DR. The first to fourth sub-peripheral circuits PERI2A to PERI2D may respectively correspond to the first to fourth mats MT1 to MT4 of the cell array structure CS.

Referring to FIGS. 7A and 7B, the ground structure GS may connect the first semiconductor substrate 100 and the second semiconductor substrate 200 in the device region DR of the first peripheral circuit structure PS1 and the second peripheral circuit PS2. The dam structure DS may include contacts and wires alternately stacked on the first semiconductor substrate 100 in the first peripheral circuit structure PS1 and the second peripheral circuit PS2.

The second semiconductor substrate 200 may include the first sub-substrate 200a, the second sub-substrate 200b, the third sub-substrate 200c, and the fourth sub-substrate 200d insulated and separated from each other. That is, the first sub-substrate 200a, the second sub-substrate 200b, the third sub-substrate 200c, and the fourth sub-substrate 200d may be spaced apart from each other through a separation insulating pattern 21 penetrating the second semiconductor substrate 200. The first sub-substrate 200a, the second sub-substrate 200b, the third sub-substrate 200c, and the fourth sub-substrate 200d may overlap with the first semiconductor substrate 100.

The first sub-substrate 200a, the second sub-substrate 200b, the third sub-substrate 200c, and the fourth sub-substrate 200d may be respectively connected to the first semiconductor substrate 100 through the ground structure GS. As described above, the ground structure GS may include the first wiring structure GS1 in the first peripheral circuit structure PS1 and the second wiring structure GS2 in the second peripheral circuit structure PS2.

The first wiring structure GS1 may include the first bonding pad BP1, the first conductive patterns CL1, and the first contacts CT1 connecting the first bonding pad BP1 and the first semiconductor substrate 100. The second wiring structure GS2 may include the second bonding pads BP2, and the backside contact BCT connecting the second bonding pads BP2 and the second semiconductor substrate 200.

The dam structure DS may include the substantially same configurations as the ground structure GS, and may have a closed curve form or ring shape, in a plan view. The dam structure DS may have the substantially same height as a height of the ground structure GS. That is, the dam structure DS may be disposed between the first semiconductor substrate 100 and the second semiconductor substrate 200. The dam structure DS may serve to protect the peripheral circuits in the device region DR from moisture or a physical crack.

Referring to FIG. 7B, the dam structure DS may include a partially different configuration from the ground structure GS. The dam structure DS may include a second penetration plug TV2 penetrating the second semiconductor substrate 200, and the second penetration plug TV2 may have a form of a closed curve or ring surrounding the device region DR in a plan view. A sidewall of the second penetration plug TV2 may be surrounded by an insulating spacer.

The cell array structure CS may include a plurality of mats MT1 and MT2, and as described above, each of the mats MT1 and MT2 may include the common source line CSL, the stack ST, the vertical structures VS, the bit lines BL, the cell contact plugs CPLG, and the peripheral contact plugs PPLG. In addition, as described above, the cell array structure CS may further include the input-output contact plugs IOPLG and the fourth bonding pads BP4. The fourth bonding pads BP4 may be bonded to the third bonding pads BP3 of the second peripheral circuit structure PS2.

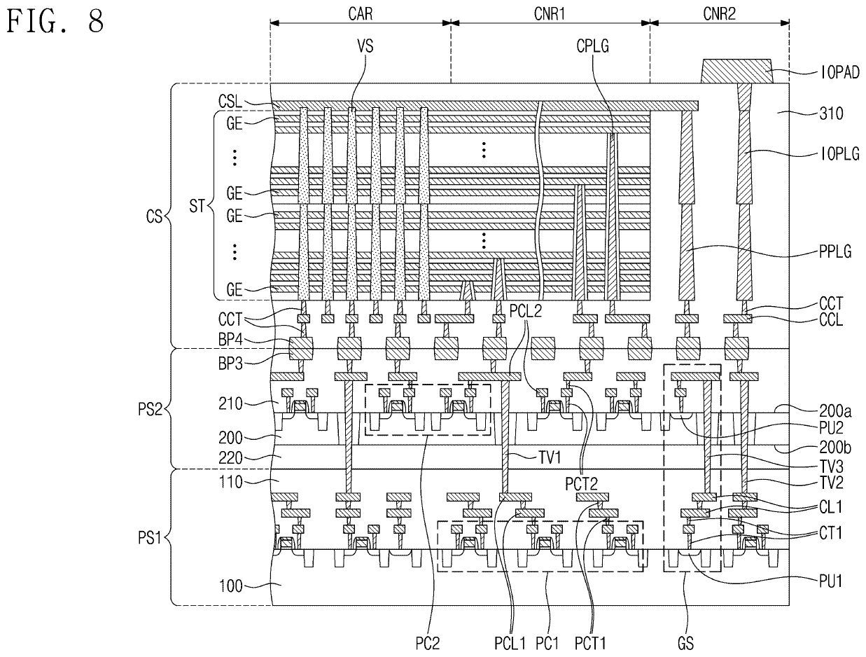

FIGS. 8, 9, 10 and 11 are cross-sectional views partially illustrating the semiconductor device according to embodiments of the disclosure. In order to simplify description, duplicate description for the same technical features as those of the semiconductor device described with reference to FIG. 4 above may be omitted, and differences between embodiments will be described.

Referring to FIG. 8, the semiconductor device may include the first peripheral circuit structure PS1, the second peripheral circuit structure PS2 on the first peripheral circuit structure PS1, and the cell array structure CS on the second peripheral circuit structure PS2.

According to embodiments, the ground structure GS may be connected between the first semiconductor substrate 100 and the second semiconductor substrate 200. According to this embodiment, the first and second bonding pads are omitted in the ground structure GS of FIG. 4, and the second semiconductor substrate 200 may be electrically connected to the first semiconductor substrate 100 through penetration plugs TV3.

Specifically, a first pick-up impurity region PU1, which may be a P-type or N-type impurity region, may be provided in the first semiconductor substrate 100, and a second pick-up impurity region PU2, which may be a P-type or N-type impurity region, may be provided in the second semiconductor substrate 200. The first pick-up impurity region PU1 and the second pick-up impurity region PU2 may include dopants having the same conductive type as, or different conductive types from each other. The first pick-up impurity region PU1 and the second pick-up impurity region PU2 may be connected to each other through the first contacts CT1, the first conductive patterns CL1, second contacts CT2, second conductive patterns CL2, and the penetration plug TV3.

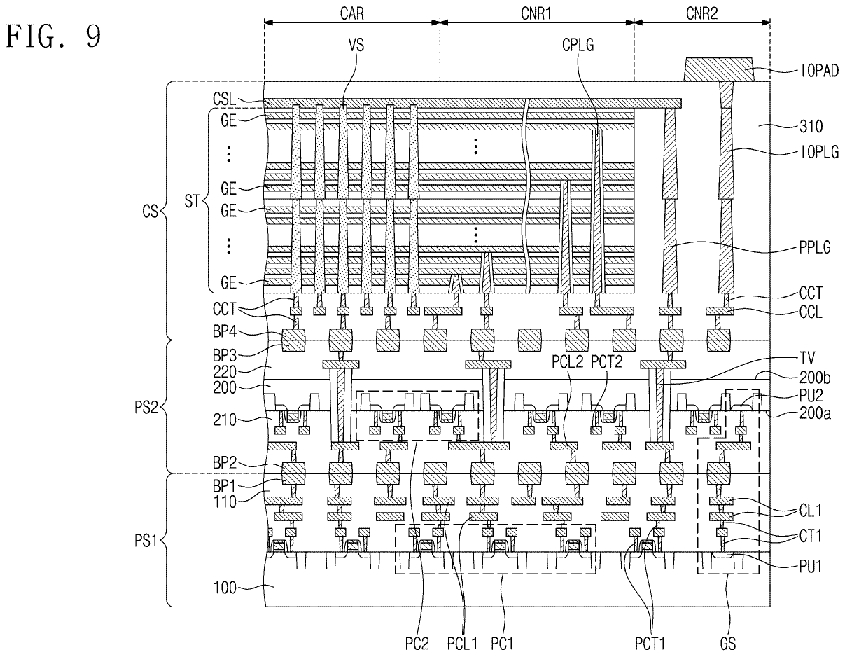

Referring to FIG. 9, the first peripheral circuit structure PS1 may include the first bonding pad BP1 in the uppermost layer of the first peripheral circuit insulating layer 110, and first pads from among the first bonding pads BP1 may be connected to the first peripheral circuits PC1. Second pads from among the first bonding pads BP1 may be connected to the first semiconductor substrate 100 through the first contacts CT1 and the first conductive patterns CL1.

The first bonding pad BP1 of the first peripheral circuit structure PS1 may be in direct contact with the second bonding pads BP2 of the second peripheral circuit structure PS2 in a bonding manner, and may be connected to each other.

The second peripheral circuit structure PS2 may include the second bonding pads BP2 in the second peripheral circuit insulating layer 210 covering the first surface 200a of the second semiconductor substrate 200, and may include the third bonding pads BP3 in the backside insulating layer 220 covering the second surface 200b of the second semiconductor substrate 200.

The second bonding pads BP2 may be connected to the second peripheral circuits PC2 through the second connection wires PCL2 and the second contact plugs PCT2. Some of the second bonding pads BP2 may be electrically connected to the second pick-up impurity region PU2 provided in the second semiconductor substrate 200.

The third bonding pads BP3 may be connected to the first peripheral circuits PC1 and the second peripheral circuits PC2 through the first penetration plugs TV1 penetrating the second semiconductor substrate 200.

The third bonding pads BP3 may be in direct contact with the fourth bonding pads BP4 of the cell array structure CS. The backside insulating layer 220 may be in direct contact with the lowermost layer of the cell interlayered insulating layer 310.

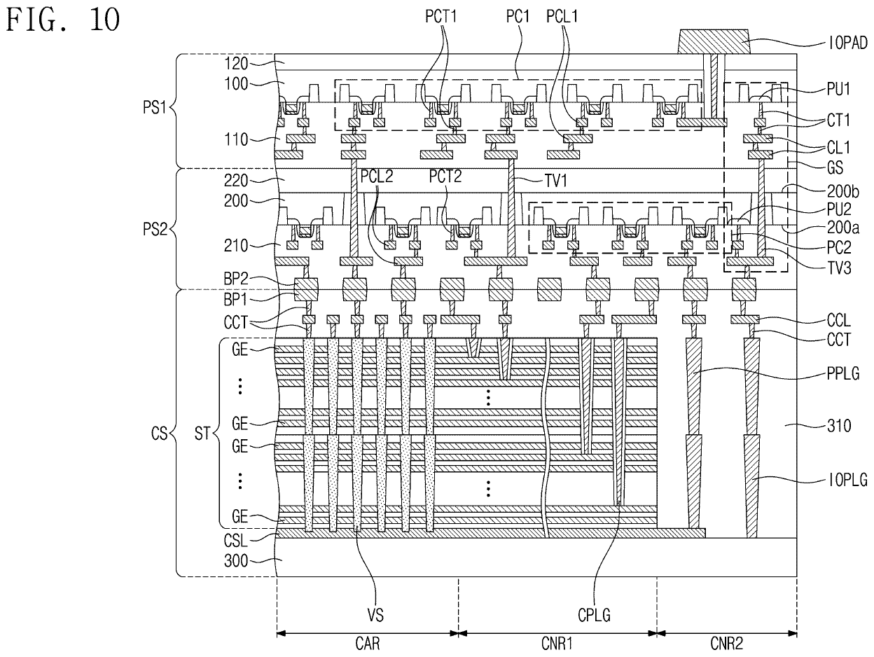

Referring to FIG. 10, the semiconductor device may include the first peripheral circuit structure PS1, the second peripheral circuit structure PS2, and the cell array structure CS.

The first peripheral circuit structure PS1 may include the first peripheral circuits PC1 integrated on the first semiconductor substrate 100. The first pick-up impurity region PU1, which may be a P-type or N-type impurity region, may be provided in the first semiconductor substrate 100.

According to embodiments, the input-output pads IOPAD may be disposed on a passivation layer 120 covering a backside of the first semiconductor substrate 100 in the first peripheral circuit structure PS1. The input-output pads IOPAD may be connected to the first peripheral circuits PC1 through the penetration plug penetrating the first semiconductor substrate 100.

The second peripheral circuit structure PS2 may include the second peripheral circuits PC2 integrated on the second semiconductor substrate 200, and the second bonding pads BP2 connected to the second peripheral circuits PC2. The second peripheral circuits PC2 may be electrically connected to the first peripheral circuits PC1 through the first penetration plugs TV1 penetrating the second semiconductor substrate 200. In addition, the second pick-up impurity region PU2, which may be a P-type or N-type impurity region, may be provided in the second semiconductor substrate 200. The second pick-up impurity region PU2 may be connected to the first pick-up impurity region PU1 through the first contacts CT1, the first conductive patterns CL1, the second contacts CT2, the second conductive patterns CL2, and the penetration plugs TV3.

As described above, the ground structure GS may be connected between the first semiconductor substrate 100 and the second semiconductor substrate 200. The ground structure GS may connect the first pick-up impurity region PU1 in the first semiconductor substrate 100 and the second pick-up impurity region PU2 in the second semiconductor substrate 200.

The cell array structure CS may include the common source line CSL, the stack ST, the vertical structures VS, and the bit lines BL disposed on the third semiconductor substrate 300.

The cell interlayered insulating layer 310 may cover the stack ST on the third semiconductor substrate 300. The first bonding pads BP1 may be provided in the cell interlayered insulating layer 310. The first bonding pads BP1 may be in direct contact with and may be connected to the second bonding pads BP2 of the second peripheral circuit structure PS2.

The input-output contact plug IOPLG in the cell array structure CS may connect the first bonding pad BP1 and the third semiconductor substrate 300.

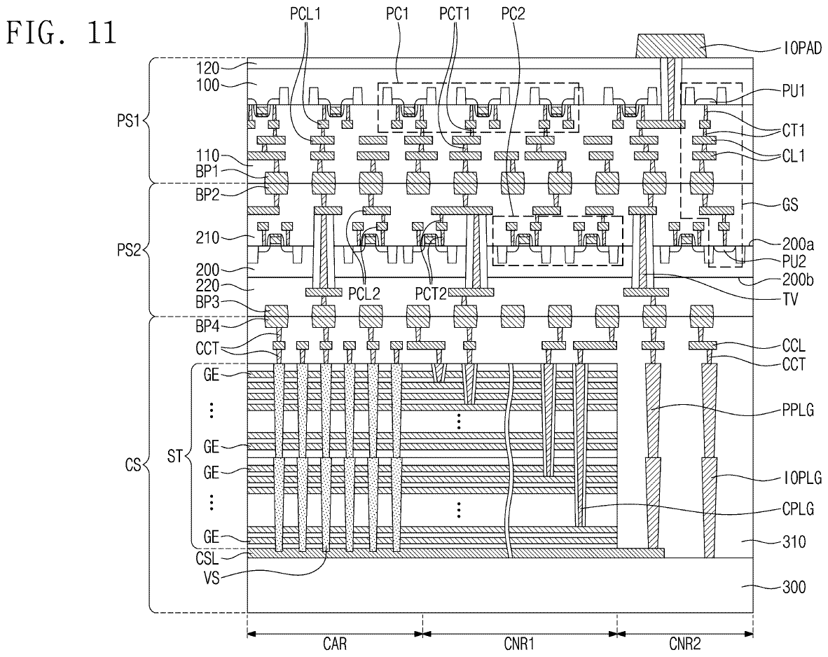

Referring to FIG. 11, the semiconductor device may include the first peripheral circuit structure PS1, the second peripheral circuit structure PS2, and the cell array structure CS.

According to embodiments, the input-output pad IOPAD may be disposed on the passivation layer 120 covering the backside of the first semiconductor substrate 100 in the first peripheral circuit structure PS1. The input-output pad IOPAD may be connected to the first peripheral circuits PC1 through the penetration plug penetrating the first semiconductor substrate 100.

The first peripheral circuit structure PS1 may include the first bonding pads BP1, and the first peripheral circuits PC1 may be electrically connected to the first bonding pads BP1.

The first pick-up impurity region PU1 may be electrically connected to at least one of the first bonding pads BP1 through the first contacts CT1 and the first conductive patterns CL1.

As described with reference to FIG. 9, the second peripheral circuit structure PS2 may include the second bonding pads BP2 in the second peripheral circuit insulating layer 210 covering the first surface 200a of the second semiconductor substrate 200, and may include the third bonding pads BP3 in the backside insulating layer 220 covering the second surface 200b of the second semiconductor substrate 200.

As described above, the ground structure GS may be connected between the first semiconductor substrate 100 and the second semiconductor substrate 200. The ground structure GS may connect the first pick-up impurity region PU1 in the first semiconductor substrate 100 and the second pick-up impurity region PU2 in the second semiconductor substrate 200. For example, the second semiconductor substrate 200 of the second peripheral circuit structure PS2 may include the second pick-up impurity regions PU2, and the second pick-up impurity region PU2 may be connected to at least one of the third bonding pads BP3 through the second conductive patterns CL2.

The second bonding pads BP2 of the second peripheral circuit structure PS2 may be bonded to the first bonding pads BP1 of the first peripheral circuit structure PS1, and the third bonding pads BP3 may be bonded to the fourth bonding pads BP4 of the cell array structure CS.

The second bonding pads BP2 of the second peripheral circuit structure PS2 may be electrically connected to the third bonding pads BP3 through the penetration plugs TV penetrating the second semiconductor substrate 200.

As described with reference to FIG. 10, the cell array structure CS may include the common source line CSL, the stack ST, the vertical structures VS and the bit lines BL disposed on the third semiconductor substrate 300.

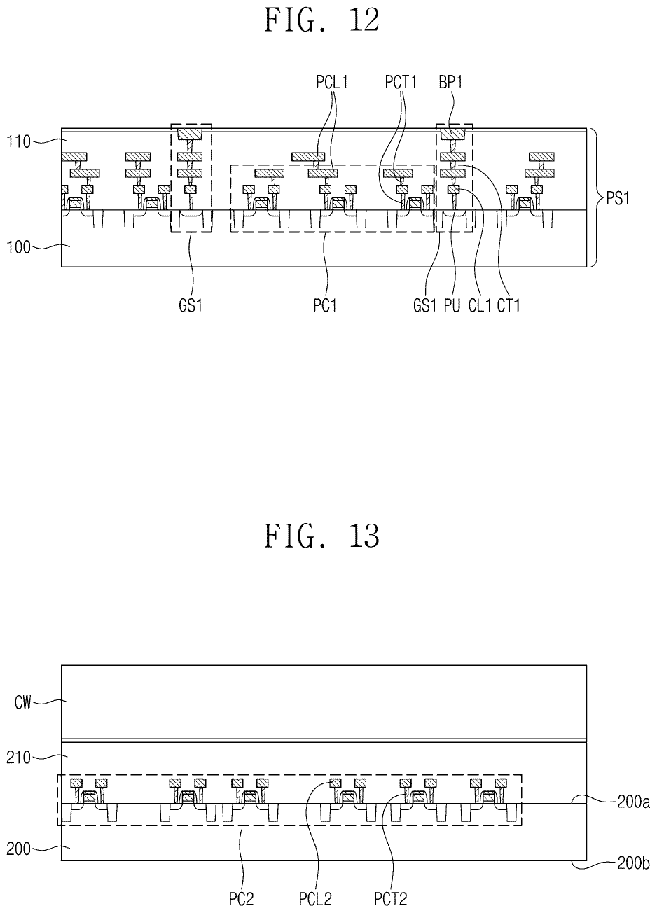

FIGS. 12 to 19 are cross-sectional views for describing a method for manufacturing a semiconductor device according to embodiments of the disclosure.

Referring to FIG. 12, the first peripheral circuit structure PS1 may be prepared, wherein the first peripheral circuit structure PS1 may include the first peripheral circuits PC1 on the first semiconductor substrate 100.

The first peripheral circuits PC1 may include some of row and column decoders, page buffers, and control circuits. The first peripheral circuits PC1 may include MOS transistors using the first semiconductor substrate 100 as a channel. For example, as described above, the first peripheral circuits PC1 may include low-voltage transistors.

More specifically, a first element separation layer defining first active regions may be formed in the first semiconductor substrate 100, first peripheral gate electrodes may be formed on the first active regions, and source and drain regions may be formed on opposite sides of the first peripheral gate electrodes.

The first peripheral circuit insulating layer 110 may cover the first peripheral circuits PC1 on the first semiconductor substrate 100. The first peripheral circuit insulating layer 110 may include one insulating layer or a plurality of stacked insulating layers.

The first connection wires PCL1 and the first contact plugs PCT1 electrically connected to the first peripheral circuits PC1 may be formed in the first peripheral circuit insulating layer 110.

According to embodiments, the first wiring structure GS1 directly connected to the first semiconductor substrate 100 may be formed during forming of the first contact plugs PCT1 and the first connection wires PCL1. The first wiring structure GS1 may include the first contacts CT1, the first conductive patterns CL1, and the first bonding pad BP1 alternately stacked.

According to some embodiments, the pick-up impurity region PU may be formed by ion-implanting an N-type or P-type dopant in the first semiconductor substrate 100 before forming the first contact plugs PCT1 and the first connection wires PCL1.

The first bonding pads BP1 may be formed in an uppermost insulating layer of the first peripheral circuit insulating layer 110. The first bonding pads BP1 may be electrically connected to the peripheral circuits through peripheral circuit wires.

The first bonding pads BP1 may be formed by using a damascene process. Upper surfaces of the first bonding pads BP1 may be substantially coplanar with an upper surface of the first peripheral circuit insulating layer 110.

Referring to FIG. 13, the second peripheral circuits PC2 may be formed on the first surface 200a of the second semiconductor substrate 200.

The second peripheral circuits PC2 may include some of the row and column decoders, the page buffers and the control circuits. The second peripheral circuits PC2 may include MOS transistors using the second semiconductor substrate 200 as a channel. For example, as described above, the second peripheral circuits PC2 may include high-voltage transistors.

More specifically, a second element separation layer defining second active regions may be formed in the second semiconductor substrate 200, second peripheral gate electrodes may be formed on the second active regions, and source and drain regions may be formed on opposite sides of the second peripheral gate electrodes.

The second peripheral circuit insulating layer 210 may cover the second peripheral circuits PC2 on the first semiconductor substrate 100. The second peripheral circuit insulating layer 210 may include one insulating layer or a plurality of stacked insulating layers.

The second contact plugs PCT2 and the second connection wires PCL2 electrically connected to the second peripheral circuits PC2 may be formed in the second peripheral circuit insulating layer 210.

Thereafter, a carrier substrate CW may be attached to an upper surface of the second peripheral circuit insulating layer 210 by using an adhesive layer. The carrier substrate CW may be a glass substrate or semiconductor substrate. For example, the adhesive layer may be a polymer tape including an insulating material.

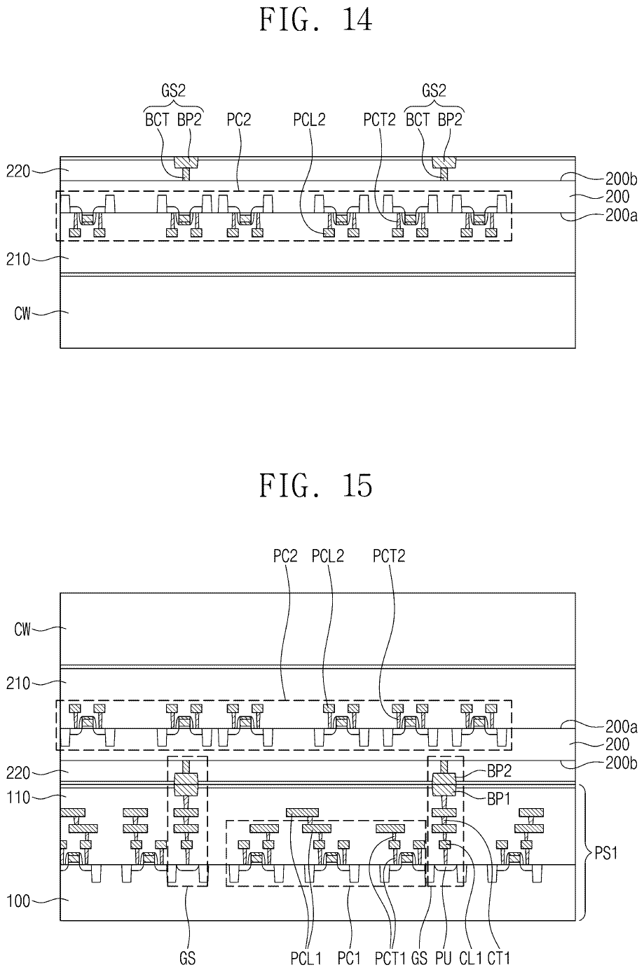

Referring to FIG. 14, the second semiconductor substrate 200 may be turned over after the carrier substrate CW is attached. Thereafter, a grinding process, a planarization process, a dry etching process, and/or a wet etching process for the second surface 200b of the second semiconductor substrate 200 may be performed. Accordingly, a thickness of the second semiconductor substrate 200 may be reduced.

Thereafter, the backside insulating layer 220 may be formed on the second surface 200b of the second semiconductor substrate 200, and the second wiring structure GS2 may be formed in the backside insulating layer 220.

The second wiring structure GS2 may include the backside contact BCT in contact with the second surface 200b of the second semiconductor substrate 200, and the second bonding pads BP2 connected to the backside contact BCT. The second bonding pads BP2 may be formed by using the damascene process. Upper surfaces of the second bonding pads BP2 may be substantially coplanar with an upper surface of the backside insulating layer 220.

Referring to FIG. 15, the second bonding pads BP2 on the carrier substrate CW and the first bonding pads BP1 of the first peripheral circuit structure PS1 may be bonded to each other.

Since the first bonding pads BP1 and the second bonding pads BP2 are bonded to each other, the ground structure GS connecting the first semiconductor substrate 100 and the second semiconductor substrate 200 may be formed. In addition, since the first bonding pads BP1 and the second bonding pads BP2 are bonded to each other, a structure on the second semiconductor substrate 200 may be turned upside down.

After the first bonding pad BP1 and the second bonding pad BP2 are bonded to each other, the carrier substrate CW may be removed.

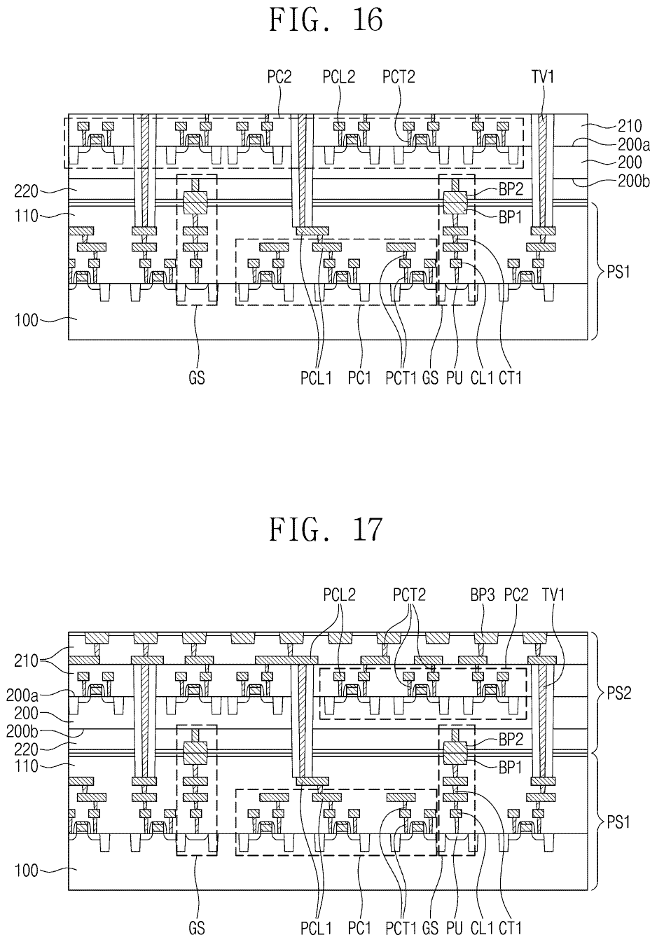

Referring to FIG. 16, the first penetration plugs TV1, penetrating the second peripheral circuit insulating layer 210 and the second semiconductor substrate 200 to be connected to the first connection wires PCL1, may be formed.

Forming the first penetration plugs TV1 may include forming a hard-mask pattern on the second peripheral circuit insulating layer 210, forming penetration holes by anisotropically etching some of the second semiconductor substrate 200 and the second peripheral circuit insulating layer 210 by using the hard-mask pattern, forming an insulating spacer covering inner walls of the penetration holes, and filling, with a conductive material, the penetration hole in which the insulating spacer is formed.

Here, for example, an anisotropically etching process for forming the penetration holes may be a process using plasma etching, reactive ion etching (RIE), inductively coupled plasma reactive ion etching (ICP-RIE), or ion beam etching (IBE).

During the anisotropically etching process using plasma, the first semiconductor substrate 100 may be located on a supporter of a semiconductor manufacturing apparatus, and a ground voltage may be applied from the supporter to the first semiconductor substrate 100 during the anisotropic etching. In addition, since the first semiconductor substrate 100 may be electrically connected to the first semiconductor substrate 100 through the ground structure GS, an arcing phenomenon may be prevented from occurring in the second semiconductor substrate 200 due to positive charges derived by ions and/or radicals included in the plasma during the anisotropically etching process.

Thereafter, referring to FIG. 17, the second peripheral circuit insulating layer 210, the second connection wires PCL2, the second contact plugs PCT2, and the third bonding pads BP3 may be formed on the penetration plugs. Accordingly, the second peripheral circuit structure PS2 may be formed on the first peripheral circuit structure PS1.

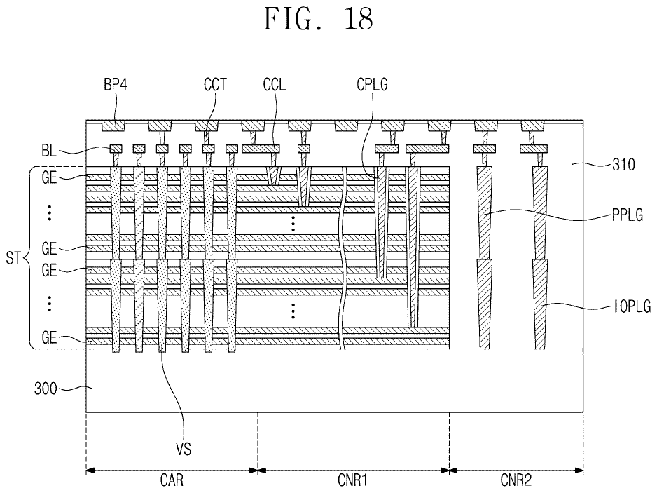

Referring to FIG. 18, a stack ST, including conductive patterns vertically stacked, may be formed on a third semiconductor substrate 300.

Forming the stack ST may include forming a mold structure in which interlayered insulating layers and sacrificial layers are vertically alternately stacked, forming the vertical structures VS penetrating the mold structure and then forming trenches penetrating the interlayered insulating layers and the sacrificial layer to expose the substrate, respectively forming the conductive patterns GE between the interlayered insulating layers by replacing, with conductive materials, the sacrificial layers exposed to the trenches, and forming separation structures by filling the trenches with an insulating material. Here, forming the vertical structures VS may include forming the channel holes penetrating the mold structure to be in contact with the substrate, sequentially depositing a data storage layer and a vertical channel layer in the vertical channel holes, and etching and planarizing the data storage layer and the vertical channel layer.

After the cell interlayered insulating layer 310 covering the stack ST is formed, bit line contact plugs respectively connected to the vertical structures VS may be formed in the cell array region CAR, and the cell contact plugs CPLG respectively connected to the conductive patterns GE of the stack ST may be formed in the first connection region CNR1.

In addition, the peripheral contact plugs PPLG and the input-output contact plugs IOPLG spaced apart from the stack ST to penetrate the cell interlayered insulating layer 310 in the second connection region CNR2 may be formed.

The bit lines BL may be formed on the cell interlayered insulating layer 310 in the cell array regions CAR, and the cell conductive lines CCL may be formed in the cell interlayered insulating layer 310 in the first connection region CNR1 and the second connection region CNR2. The bit lines BL may be connected to the bit line contact plugs, and the cell conductive lines CCL may be connected to the cell contact plugs CPLG, the peripheral contact plugs PPLG, and the input-output contact plugs IOPLG.

Thereafter, the fourth bonding pads BP4 may be formed in an uppermost insulating layer of the cell interlayered insulating layer 310. The fourth bonding pads BP4 may be electrically connected to the conductive patterns GE of the stack ST and the bit lines BL through the contact plugs and the wires. The fourth bonding pads BP4 may be formed by using the damascene process. Upper surfaces of the fourth bonding pads BP4 may be substantially coplanar with an upper surface of the cell interlayered insulating layer 310.

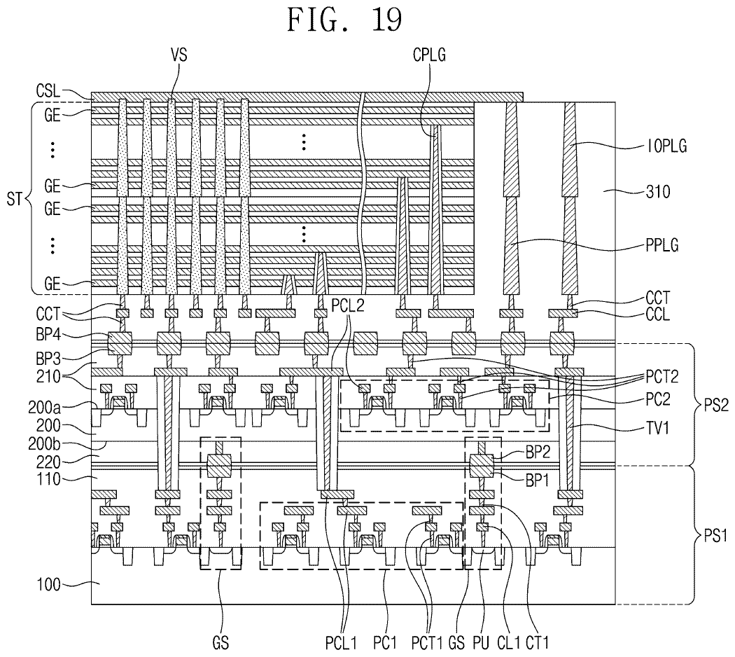

Referring to FIG. 19, after the fourth bonding pads BP4 are formed, the stack ST may be turned upside down so that the fourth bonding pads BP4 may be bonded to the third bonding pads BP3 of the second peripheral circuit structure PS2. Accordingly, an uppermost layer (lowermost in FIG. 19) of the cell interlayered insulating layer 310 of the cell array structure CS and an uppermost layer of the second peripheral circuit insulating layer 210 of the second peripheral circuit structure PS2 may be bonded to each other.

Thereafter, the third semiconductor substrate 300 may be removed. Removing the third semiconductor substrate 300 may include a grinding process, a planarization process, a dry etching process, and a wet etching process. Since the third semiconductor substrate 300 is removed, lower surfaces of the vertical structures VS and a lowermost layer (uppermost in FIG. 19) of the interlayered insulating layer of the stack ST may be exposed.

Thereafter, the common source line CSL may be formed on lower surfaces (upper surfaces in FIG. 19) of the vertical structures VS. The common source line CSL may be an impurity region doped with an impurity, or may be composed of a conductive material. The common source line CSL may continuously extend from the cell array region CAR to the first connection region CNR1.

Subsequently, referring to FIG. 4, a capping insulating layer covering the cell interlayered insulating layer 310 and the common source line CSL may be formed, and the input-output pads IOPAD may be formed on the capping insulating layer. The input-output pads IOPAD may be connected to the input-output contact plug IOPLG through the contact plug penetrating the capping insulating layer. The capping insulating layer may include silicon oxide, silicon nitride, or silicon oxynitride.

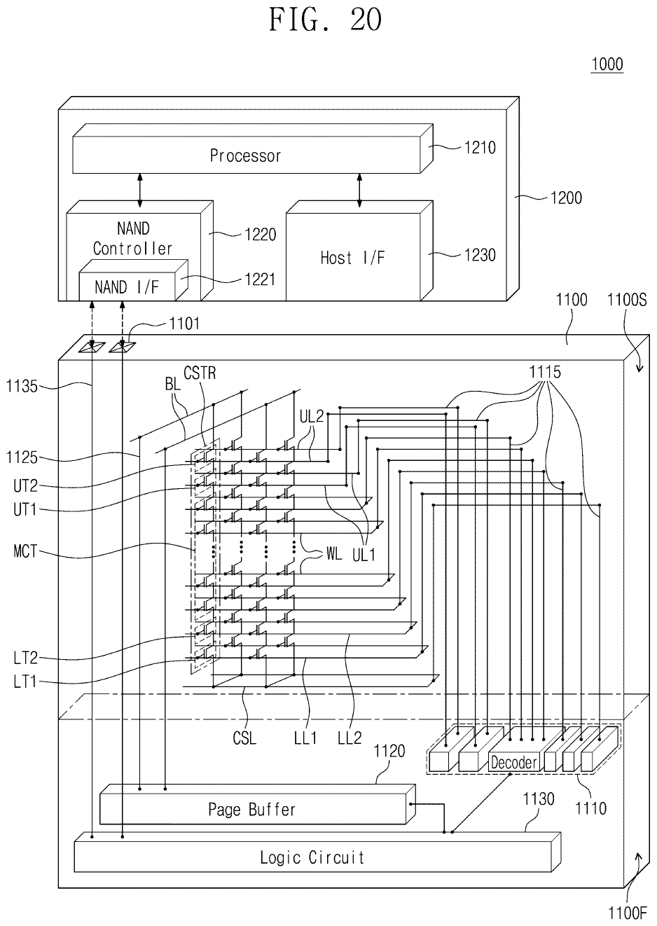

FIG. 20 is a diagram schematically illustrating an electronic system including a semiconductor memory device according to an embodiment of the disclosure.

Referring to FIG. 20, an electronic system 1000 according to an embodiment of the disclosure may include a semiconductor device 1100 and a controller 1200 electrically connected to the semiconductor device 1100. The electronic system 1000 may be a storage device including one or more of the semiconductor device 1100 or an electronic device including the storage device. For example, the electronic system 1000 may be a solid state drive (SSD) device, a universal serial bus (USB), a computing system, a medical device, or a communication device including the one or more of the semiconductor device 1100.

The semiconductor device 1100 may be an involatile memory device, and may be, for example, a NAND flash memory device. The semiconductor device 1100 may include a first structure 1100F and a second structure 1100S on the first structure 1100F. According to embodiments, the first structure 1100F may be disposed beside the second structure 1100S.

The first structure 1100F may be a peripheral circuit structure including a decoder circuit 1110, a page buffer 1120 and a logic circuit 1130. The second structure 1100S may be a memory cell structure including the bit line BL, the common source line CSL, the word lines WL, a first gate lower line LL1, a second gate lower line LL2, a first gate upper line UL1, a second gate upper line UL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. A number of the lower transistors LT1 and LT2 and a number of the upper transistors UT1 and UT2 may be variously changed according to embodiments.

According to embodiments, the upper transistors UT1 and UT2 may include a string selection transistor, and the lower transistors LT1 and LT2 may include a ground selection transistor. The first gate lower line LL1 and the second gate lower line LL2 may be gate electrodes of the lower transistors LT1 and LT2, respectively. The word lines WL may be gate electrodes of the memory cell transistors MCT. The gate upper lines (e.g., the first gate upper line UL1 and the second gate upper line UL2) may be gate electrodes of the upper transistors UT1 and UT2, respectively.

According to embodiments, the lower transistors LT1 and LT2 may include a lower erase control transistor (e.g., the lower transistor LT1) and a ground selection transistor (e.g., the lower transistor LT2) serially connected to each other. For example, the upper transistors UT1 and UT2 may include a string selection transistor (e.g., the upper transistor UT1) and an upper erase control transistor (e.g., the upper transistor UT2) serially connected to each other. At least one of the lower erase control transistor (e.g., the lower transistor LT1) or the upper erase control transistor (e.g., the upper transistor UT2) may be used in an erase operation of deleting data stored in the memory cell transistors MCT using a gate-induced drain leakage (GIDL) phenomenon.

The common source line CSL, the first gate lower line LL1, the second gate lower line LL2, the word lines WL, the first gate upper line UL1, and second gate upper line UL2 may be electrically connected to the decoder circuit 1110 through first connection wires 1115 extending from an inside of the first structure 1100F to the second structure 1100S. The bit lines BL may be electrically connected to the page buffer 1120 through second connection wires 1125 extending from the inside of the first structure 1100F to the second structure 1100S.

In the first structure 1100F, the decoder circuit 1110 and the page buffer 1120 may perform an operation of controlling at least one selection memory cell transistor from among a plurality of memory cell transistors MCT. The decoder circuit 1110 and the page buffer 1120 may be controlled by the logic circuit 1130. The semiconductor device 1100 may communicate with the controller 1200 through an input-output pad 1101 electrically connected to the logic circuit 1130. The input-output pad 1101 may be electrically connected to the logic circuit 1130 through an input-output connection wire 1135 extending from the inside of the first structure 1100F to the second structure 1100S.

According to an embodiment, the first structure 1100F may include a voltage generator 3 (see FIG. 2). The voltage generator 3 may generate the program voltage, the read voltage, the pass voltage, the verification voltage, and the like for an operation of the memory cell strings CSTR. Here, the program voltage may be relatively higher (e.g., about 20 V to about 40 V) than the read voltage, the pass voltage, and the verification voltage.

According to embodiments, the first structure 1100F may include high-voltage transistors and low-voltage transistors. The decoder circuit 1110 may include pass transistors connected to the word lines WL of the memory cell strings CSTR. The pass transistors may include the high-voltage transistors capable of tolerating a high-voltage such as the program voltage applied to the word lines WL during a program operation.

The controller 1200 may include a processor 1210, a NAND controller 1220, and a host interface 1230. According to embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to a predetermined firmware, and may control the NAND controller 1220 to access to the semiconductor device 1100. The NAND controller 1220 may include a NAND interface 1221 that processes communication with the semiconductor device 1100. A control command for controlling the semiconductor device 1100, data to be recorded in the memory cell transistors MCT of the semiconductor device 1100, data to be read from the memory cell transistors MCT of the semiconductor device 1100, or the like may be transferred through the NAND interface 1221. The host interface 1230 may provide a communication function between the electronic system 1000 and an external host. When the control command is received from the external host through the host interface 1230, the processor 1210 may control the semiconductor device 1100 in response to the control command.

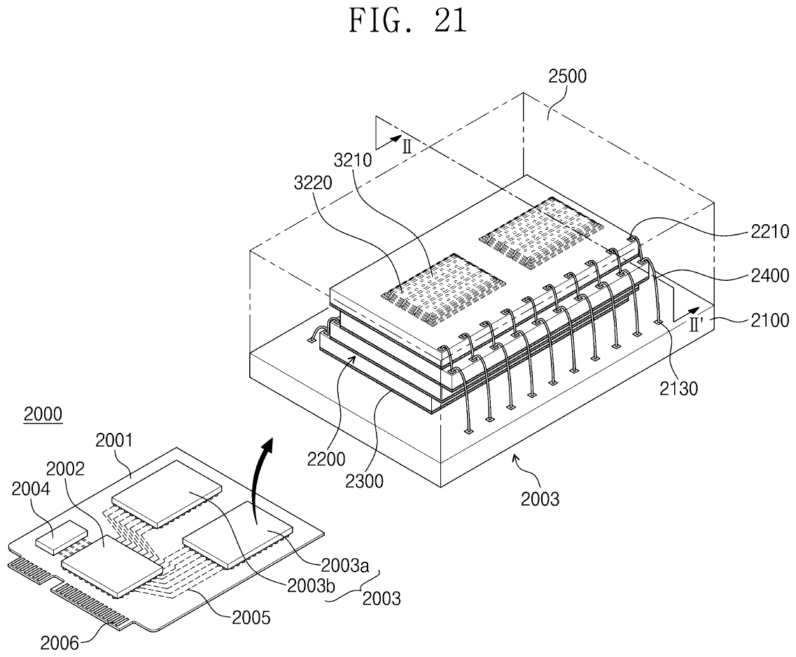

FIG. 21 is a perspective view schematically illustrating an electronic system including a semiconductor device according to embodiments of the disclosure.

Referring to FIG. 21, an electronic system 2000 according to an embodiment of the disclosure may include a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins coupled with an external host. A number and disposition of the plurality of pins may be changed in the connector 2006 according to communication interface between the electronic system 2000 and the external host. According to embodiments, the electronic system 2000 may communicate with the external host according to any one among interfaces such as a universal serial bus (USB), a peripheral component interconnect express (PCI-Express), a serial advanced technology attachment (SATA), M-Phy for a universal flash storage (UFS). According to embodiments, the electronic system 2000 may operate by a power supplied by the external host through the connector 2006. The electronic system 2000 may further include a power management integrated circuit (PMIC) that distributes the power supplied by the external host to the controller 2002 and the semiconductor package 2003.

The controller 2002 may write data to the semiconductor package 2003, or may read data from the semiconductor package 2003, and may improve an operation speed of the electronic system 2000.

The DRAM 2004 may be a buffer memory for mitigating a difference of speeds of the semiconductor package 2003, which is a data storage space, and the external host. The DRAM 2004 included in the electronic system 2000 may operate as a kind of a cash memory, and may provide a space for temporarily storing data in an operation of controlling the semiconductor package 2003. When the DRAM 2004 is included in the electronic system 2000, the controller 2002 may further include a DRAM controller for controlling the DRAM 2004 as well as the NAND controller for controlling the semiconductor package 2003.

The semiconductor packages 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, semiconductor chips 2200 on the package substrate 2100, adhesive layers 2300 disposed on a lower surface of each of the semiconductor chips 2200, a connection structure 2400 electrically connecting the package substrate 2100 and the semiconductor chips 2200, and a molding layer 2500 covering the semiconductor chips 2200 and the connection structure 2400 on the package substrate 2100.

The package substrate 2100 may be a printed circuit board including upper pads 2130. Each of the semiconductor chips 2200 may include an input-output pad 2210. The input-output pad 2210 may correspond to the input-output pad 1101 of FIG. 20. Each of the semiconductor chips 2200 may include stack structures 3210 and vertical structures 3220. Each of the semiconductor chips 2200 may include the semiconductor device according to embodiments of the disclosure to be described later.

According to embodiments, the connection structure 2400 may be a bonding wire electrically connecting the input-output pads 2210 and the upper pads 2130. Accordingly, in each of the first semiconductor package 2003a and the second semiconductor package 2003b, the semiconductor chips 2200 may be electrically connected to each other in a bonding wire manner, and may be electrically connected to the upper pads 2130 of the package substrate 2100. According to embodiments, in each of the first semiconductor package 2003a and the second semiconductor package 2003b, the semiconductor chips 2200 may be electrically connected to each other by a connection structure including a through silicon via (TSV), instead of the connection structures 2400 of the bonding wire manner.

According to embodiments, the semiconductor chips 2200 and the controller 2002 may be included in one package. According to embodiments, the semiconductor chips 2200 and the controller 2002 may be mounted on the main substrate 2001 and another separate interposer substrate, and may be connected to each other by a wire formed on the interposer substrate.

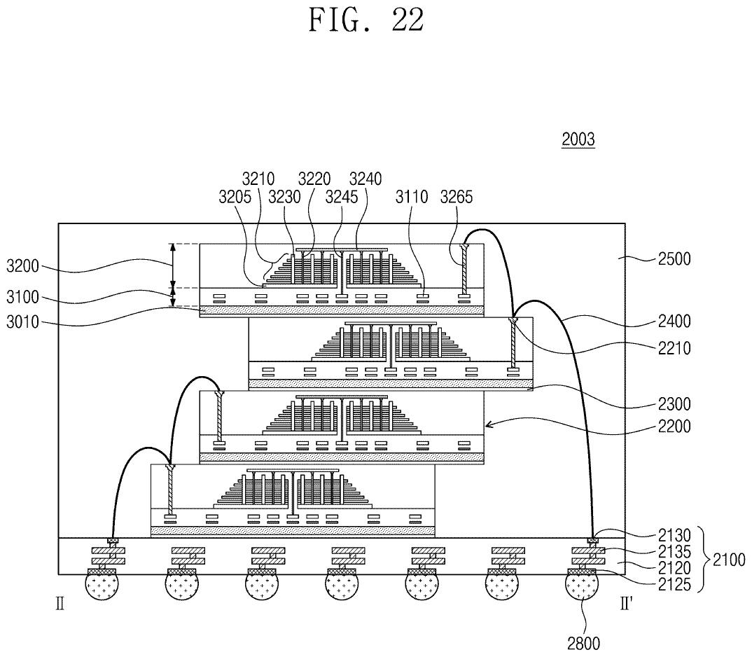

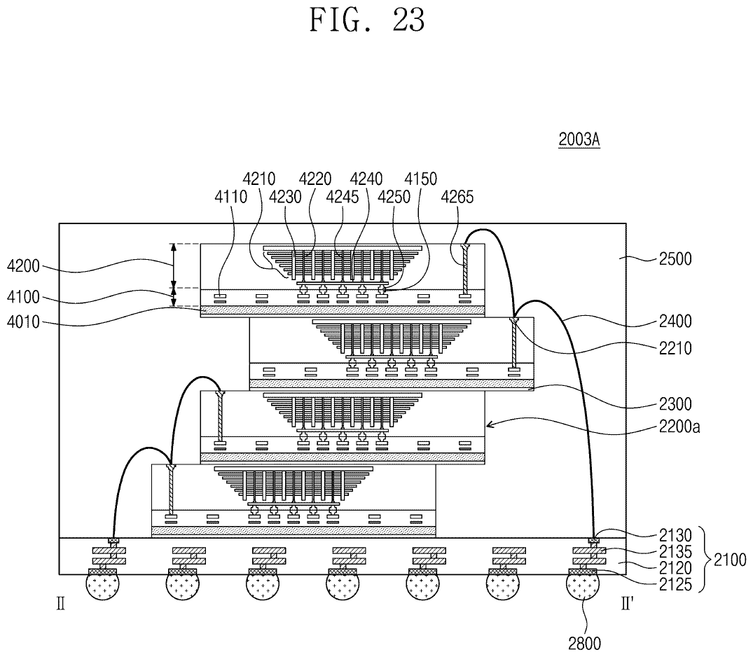

FIGS. 22 and 23 are cross-sectional views schematically illustrating the semiconductor packages according to an embodiment of the disclosure, and conceptually illustrate a region taken along a line II-II′ of the semiconductor package of FIG. 21.

Referring to FIG. 22, the package substrate 2100 may be a printed circuit board in the semiconductor package 2003. The package substrate 2100 may include a package substrate body portion 2120, upper pads 2130 (see FIG. 21) disposed on an upper surface of the package substrate body portion 2120, or exposed through the upper surface of the package substrate body portion 2120, lower pads 2125 disposed on a lower surface of the package substrate body portion 2120, or exposed through the lower surface of the package substrate body portion 2120, and internal wires 2135 electrically connecting the lower pads 2125 and the upper pads 2130 inside the package substrate body portion 2120. The upper pads 2130 may be electrically connected to connection structures 2400. Like FIG. 21, the lower pads 2125 may be connected to the wiring patterns 2005 of the main substrate 2010 of the electronic system 2000 through conductive connection portions 2800.

Each of the semiconductor chips 2200 may include a semiconductor substrate 3010, and a first structure 3100 and a second structure 3200 sequentially stacked on the semiconductor substrate 3010. The first structure 3100 may include a peripheral circuit region including peripheral wires 3110. The second structure 3200 may include a source structure 3205, a stack structure 3210 on the source structure 3205, vertical structures 3220 and separation structures 3230 penetrating the stack structure 3210, bit lines 3240 electrically connected to the vertical structures 3220, and cell contact plugs electrically connected to the word lines WL (see FIG. 20) of the stack structure 3210. Each of the first structure 3100, the second structure 3200, and the semiconductor chips 2200 may further include separation structures 3230 described below.

Each of the semiconductor chips 2200 may include a penetration wire 3245 electrically connected to the peripheral wires 3110 of the first structure 3100, and extending into the second structure 3200. The penetration wire 3245 may be disposed outside the stack structure 3210, and may be further disposed so as to penetrate the stack structures 3210. Each of the semiconductor chips 2200 may further include an input-output connection wire 3265 electrically connected to the peripheral wires 3110 of the first structure 3100, and extending into the second structure 3200, and the input-output pad 2210 electrically connected to the input-output connection wire 3265.

Referring to FIG. 23, in the semiconductor package 2003A, each of the semiconductor chips 2200 may include a semiconductor substrate 4010, a first structure 4100 on the semiconductor substrate 4010, and a second structure 4200 bonded to the first structure 4100 on the first structure 4100 in a wafer bonding manner.

The first structure 4100 may include a peripheral circuit region including a peripheral wire 4110 and a first adhesive structures 4150. The second structure 4200 may include a source structure, a stack structure 4210 between the source structure and the first structure 4100, vertical structures 4220 and a separation structure 4230 penetrating the stack structure 4210, and second adhesive structures 4250 respectively electrically connected to the word lines WL (see FIG. 20) of the stack structure 4210 and the vertical structures 4220. For example, the second adhesive structures 4250 may be electrically connected to the vertical structures 4220 and the word lines WL (see FIG. 20) through the bit lines 4240 electrically connected to the vertical structures 4220 and the cell contact plugs electrically connected to the word lines WL (see FIG. 20). The first adhesive structures 4150 of the first structure 4100 and the second adhesive structures 4250 of the second structure 4200 may be in contact with each other to be bonded to each other. For example, bonding parts of the first adhesive structures 4150 and the second adhesive structures 4250 may be formed of copper.

Each of the first structure 4100, the second structure 4200, and the semiconductor chips 2200 may further include a source structure. Each of the semiconductor chips 2200 may further include the input-output pad 2210 electrically connected to the peripheral wires 4110 of the first structure 4100 and the input-output connection wire 4265 of a lower portion of the input-output pad 2210. The input-output connection wire 4265 may be electrically connected to the peripheral wires 4110 of the first structure 4100.

The semiconductor chips 2200 of FIG. 22 or the semiconductor chips 2200a of FIG. 23 may be electrically connected to each other by the connection structures 2400 having a bonding wire form. However, according to embodiments, the semiconductor chips 2200 and 2200a in one semiconductor package including the semiconductor chips 2200 of FIG. 22 and the semiconductor chips 2200a of FIG. 23 may be electrically connected to each other by a connection structure including a through silicon via TSV.

The first structure 3100 of FIG. 22 and the first structure 4100 of FIG. 23 may correspond to first and second peripheral circuit structures according to embodiments described above, and the second structure 3200 of FIG. 22 and the second structure 4200 of FIG. 23 may correspond to a cell array structure according to embodiments described above.

According to embodiments of the disclosure, a semiconductor device may include cell array structures and first and second peripheral circuit structures vertically stacked, and a ground structure may be provided between first and second semiconductor substrates of the first and second peripheral circuit structures, and thus the second semiconductor substrate may be maintained in a grounded state during a process of manufacturing the semiconductor device, thereby preventing an arcing phenomenon.

Although non-limiting example embodiments of the disclosure have been described, it is understood that the disclosure is not limited to these example embodiments. Various changes and modifications can be made by one ordinary skilled in the art within the spirit and scope of the present disclosure. Therefore, it should be understood that the embodiments described above are examples in all respects and are not intended to be limiting.

What is claimed is:

1. A semiconductor device comprising:
a first peripheral circuit structure comprising a first semiconductor substrate, and a first peripheral circuit on the first semiconductor substrate;
a second peripheral circuit structure vertically overlapping with the first peripheral circuit structure, the second peripheral circuit structure comprising a second semiconductor substrate, and a second peripheral circuit on the second semiconductor substrate; and
a cell array structure vertically overlapping with the first peripheral circuit structure and the second peripheral circuit structure, the cell array structure comprising memory cells that are three-dimensionally arranged,
wherein the first peripheral circuit structure comprises a first wiring structure comprising a first bonding pad, the first bonding pad connected to the first semiconductor substrate, and
wherein the second peripheral circuit structure comprises a second wiring structure comprising a second bonding pad, the second bonding pad connected to the second semiconductor substrate and bonded to the first bonding pad.

2. The semiconductor device of claim 1, wherein the second semiconductor substrate comprises a first surface and a second surface opposite to the first surface,
wherein the second peripheral circuit is on the first surface of the second semiconductor substrate,
wherein the second peripheral circuit structure further comprises a backside insulating layer on the second surface of the second semiconductor substrate, and
wherein the second bonding pad is in the backside insulating layer.

3. The semiconductor device of claim 1, wherein the second semiconductor substrate comprises a first surface and a second surface opposite to the first surface,
wherein the first peripheral circuit structure further comprises a first connection wire connected to the first peripheral circuit, and
wherein the second peripheral circuit structure further comprises:
a second connection wire connected to the second peripheral circuit, the second connection wire being on the first surface of the second semiconductor substrate; and
a through plug penetrating the second semiconductor substrate, the through plug connecting the first connection wire to the second connection wire.

4. The semiconductor device of claim 1, wherein the first wiring structure is electrically insulated from the first peripheral circuit.

5. The semiconductor device of claim 1, wherein the first wiring structure comprises a contact plug connected to a pick-up impurity region of the first semiconductor substrate.

6. The semiconductor device of claim 1, wherein the second semiconductor substrate comprises a plurality of sub-substrates separated from each other, and
wherein the first wiring structure and the second wiring structure are respectively connected to the plurality of sub-substrates.

7. The semiconductor device of claim 6, wherein the first semiconductor substrate comprises a device region and an edge region around the device region, and
wherein the first peripheral circuit structure further comprises a dam structure in the edge region.

8. The semiconductor device of claim 7, wherein the dam structure is in contact with an upper surface of the first semiconductor substrate and a lower surface of the second semiconductor substrate.

9. The semiconductor device of claim 7, wherein the plurality of sub-substrates overlap with the device region of the first semiconductor substrate.

10. The semiconductor device of claim 1, wherein the second peripheral circuit structure further comprises a third bonding pad connected to the second peripheral circuit,
wherein the cell array structure further comprises a fourth bonding pad connected to at least one of the memory cells, and
wherein the fourth bonding pad is bonded to the third bonding pad.

11. The semiconductor device of claim 1, wherein the cell array structure comprises:
a stack comprising conductive patterns that are vertically stacked;
vertical structures penetrating the stack; and
cell contact plugs respectively connected to pad portions of the conductive patterns.

12. The semiconductor device of claim 11, wherein the first wiring structure and the second wiring structure vertically overlap with the stack of the cell array structure.

13. A semiconductor device comprising:
a first peripheral circuit structure comprising:
a first semiconductor substrate;
a first peripheral circuit on the first semiconductor substrate; and
a first bonding pad connected to the first semiconductor substrate;
a second peripheral circuit structure vertically overlapping with the first peripheral circuit structure; and
a cell array structure vertically overlapping with the first peripheral circuit structure and the second peripheral circuit structure, the cell array structure comprising memory cells that are three-dimensionally arranged,
wherein the second peripheral circuit structure comprises:
a second semiconductor substrate comprising a first surface and a second surface opposite to the first surface;
a second peripheral circuit on the first surface of the second semiconductor substrate;
a second bonding pad connected to the second surface of the second semiconductor substrate;
a third bonding pad connected to the second peripheral circuit, the third bonding pad being on the first surface of the second semiconductor substrate; and
a through plug penetrating the second semiconductor substrate and connecting the first peripheral circuit and the second peripheral circuit, and
wherein the first bonding pad is bonded to the second bonding pad.

14. The semiconductor device of claim 13, wherein the first peripheral circuit structure further comprises a first connection wire connected to the first peripheral circuit,
wherein the second peripheral circuit structure further comprises a second connection wire connecting the second peripheral circuit and the third bonding pad, the second connection wire being on the first surface of the second semiconductor substrate, and
wherein the through plug connects the second connection wire to the first connection wire.

15. The semiconductor device of claim 13, wherein the cell array structure further comprises a fourth bonding pad connected to at least one of the memory cells, and
the fourth bonding pad is bonded to the third bonding pad.

16. The semiconductor device of claim 15, further comprising:
an input-output pad on the cell array structure; and
an input-output contact plug partially penetrating the cell array structure, the input-output contact plug connecting the input-output pad and the fourth bonding pad.

17. The semiconductor device of claim 13, wherein the cell array structure further comprises:
a stack comprising conductive patterns that are vertically stacked;
vertical structures penetrating the stack; and
cell contact plugs respectively connected to pads of the conductive patterns.

18. An electronic system comprising:
a semiconductor device comprising:
a first peripheral circuit structure;
a second peripheral circuit structure on the first peripheral circuit structure; and
a cell array structure on the second peripheral circuit structure; and
a controller electrically connected to the semiconductor device via an input-output pad, the controller configured to control the semiconductor device,
wherein the first peripheral circuit structure comprises:
a first semiconductor substrate;
a first peripheral circuit on the first semiconductor substrate;
a first connection wire connected to the first peripheral circuit, and
a first bonding pad,
wherein the second peripheral circuit structure comprises:
a second semiconductor substrate;
a second peripheral circuit on a first surface of the second semiconductor substrate;
a second connection wire connected to the second peripheral circuit;
a second bonding pad connected to the second connection wire; and
a third bonding pad bonded to the first bonding pad, and
wherein the first bonding pad of the first peripheral circuit structure is connected to the first semiconductor substrate.

19. The electronic system of claim 18, wherein the second semiconductor substrate further comprises a second surface opposite to the first surface, and
wherein the third bonding pad is connected to the second surface of the second semiconductor substrate.

20. The electronic system of claim 18, wherein the cell array structure comprises:
memory cells vertically overlapping with the first peripheral circuit structure and the second peripheral circuit structure, the memory cells being three-dimensionally arranged,
a fourth bonding pad connected to at least one of the memory cells, and
wherein the fourth bonding pad is bonded to the second bonding pad.
